(19) United States
(12) Patent Application Publication
(10) Pub. No.: US 2012/0048332 A1
(43) Pub. Date: Mar. 1, 2012

(54) ADHESIVE FILM FOR SOLAR CELL ELECTRODE AND METHOD FOR MANUFACTURING SOLAR CELL MODULE USING THE SAME

(75) Inventors: Shigenori Shimizu, Tsukuba-shi (JP); Hiroyuki Izawa, Tsukuba-shi (JP); Keisuke Ookubo, Chikusei-shi (JP); Shigeaki Funyu, Tsukuba-shi (JP); Yutaka Okada, Tsukuba-shi (JP); Keiko Funyu, Tsukuba-shi (JP); Naotaka Tanaka, Tsuchiura-shi (JP)

(73) Assignee: HITACHI CHEMICAL COMPANY, LTD., Tokyo (JP)

(21) Appl. No.: 13/217,666

(22) Filed: Aug. 25, 2011

(30) Foreign Application Priority Data
Aug. 26, 2010 (JP) P2010-189618
Jul. 8, 2011 (JP) P2011-151932

(51) Int. Cl. H01L 31/05; H01L 31/18; C09J 133/00; C09J 163/02; C09J 171/10

(52) U.S. Cl. 136/244; 525/109; 525/523; 438/73; 257/E31.001

(57) ABSTRACT

There are provided an adhesive film for a solar cell electrode providing a solar cell capable of reducing adverse effects on photovoltaic cells caused by heating or pressure and having sufficient solar cell characteristics, and a method for manufacturing a solar cell module using the same. The adhesive film for a solar cell electrode is an adhesive film used for electrical connection between photovoltaic cell surface electrodes and wiring members, wherein the adhesive film contains a crystalline epoxy resin, a curing agent and a film forming material.

### BACKGROUND OF THE INVENTION

1. Field of the Invention

The present invention relates to an adhesive film for a solar cell electrode and a method for manufacturing a solar cell module using the same.

2. Related Background Art

Solar cell modules have a construction wherein a plurality of photovoltaic cells are connected in series and/or in parallel via wiring members which are electrically connected to their surface electrodes. Since solar cells are used in an outdoor environment, photovoltaic cell groups having wiring members are typically sealed with a sealing material in order to secure tolerance against temperature change, moistness, a strong wind or snow coverage. After a sealing material made of tempered glass, ethylene vinyl acetate (EVA) or a back sheet or the like is laminated on photovoltaic cell groups having wiring members with the sealing material interposed between the photovoltaic cell groups and a vacuum laminator, sealing is usually performed by the vacuum laminator.

Solder has been conventionally used for connection between photovoltaic cell surface electrodes and wiring members during the fabrication of solar cell modules (see Patent Documents (JP 2004-204256 A and JP 2005-050780 A), for example). The solder is widely used because of its excellent connection reliability, including conductivity and anchoring strength, low cost and general applicability.

Connection methods which do not employ solder are also known. For example, connection methods using conductive paste are disclosed in Patent Documents (JP 2000-286436 A, JP 2001-357897 A, and JP 3448924 B), and connection methods using a conductive film are disclosed in Patent Documents (JP 2005-101519 A, JP 2007-214533 A and JP 2008-300403 A).

In the method for connection between the photovoltaic cell surface electrodes and the wiring members using the solder, the high temperature of connection and the volume shrinkage of the solder adversely affect the semiconductor structure of the photovoltaic cell, which may result in degraded characteristics of the photovoltaic cells because a solder melting temperature is usually about 230 to 260° C.

On the other hand, as described in the above-mentioned Patent Documents (JP 2000-286436 A, JP 2001-357897 A, and JP 3448924 B), the methods for connection between the photovoltaic cell surface electrodes and the wiring members using the conductive paste may considerably degrade the characteristics with time under a high-temperature and high-humidity condition, and do not necessarily provide sufficient connection reliability.

As described in the above-mentioned Patent Documents (JP 2005-101519 A, JP 2007-214533 A and JP 2008-300403 A), since the methods for connection between the photovoltaic cell surface electrodes and the wiring members using the conductive film enable adhesion at a temperature lower than that of the solder, the methods can suppress adverse effects on the photovoltaic cells produced when the solder is used. However, nevertheless, it is necessary to apply a pressure of about several MPa simultaneously with heating of nearly 200° C. for connection, which has large adverse effects on the photovoltaic cells.

The present invention has been accomplished in view of the problem of the above-mentioned conventional art, and it is an object of the present invention to provide an adhesive film for a solar cell electrode providing a solar cell capable of reducing adverse effects on photovoltaic cells caused by heating or pressure and having sufficient solar cell characteristics, and a method for manufacturing a solar cell module using the same.

### SUMMARY OF THE INVENTION

In order to solve the above-mentioned problem, the present invention provides an adhesive film for a solar cell electrode used for electrical connection between photovoltaic cell surface electrodes and wiring members, wherein the adhesive film comprises a crystalline epoxy resin, a curing agent and a film forming material.

The adhesive film for a solar cell electrode of the present invention having the above-mentioned configuration can attain both the stability of the film at room temperature and low-temperature fluidity in connection between the electrodes and the wiring members, and can sufficiently reduce adverse effects on photovoltaic cells caused by heating or pressure. Although various liquid epoxies improving fluidity are known, the adhesive film itself is excessively softened in a method in which only the liquid epoxies are mixed, to cause a problem such as oozing before use.

Since the adhesive film for a solar cell electrode of the present invention can sufficiently join the photovoltaic cell surface electrodes to the wiring members under temperature and pressure conditions in a laminating step of a sealing material, it is possible to omit a contact bonding step performed when the conventional conductive film is used, and to perform mounting collectively with the sealing material in only the laminating step. Thereby, it is possible to simplify the manufacturing step of the solar cell module.

In the adhesive film for a solar cell electrode of the present invention, it is preferable that the above-mentioned curing agent be a latent curing agent. In this case, film stability at room temperature can be easily secured.

It is preferable that the above-mentioned crystalline epoxy resin be a bisphenol type epoxy resin or a biphenyl type epoxy resin in that a melting point is comparatively low.

Furthermore, it is preferable that the above-mentioned crystalline epoxy resin be a bisphenol type epoxy resin in that a melting point is further comparatively low.

It is preferable that the above-mentioned bisphenol type epoxy resin be a compound represented by formula (2-1).

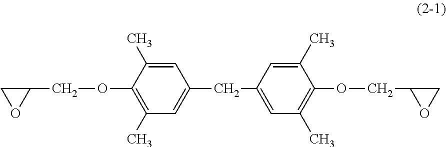

It is preferable that the above-mentioned film forming material comprise a phenoxy resin. It is preferable that the above-mentioned film forming material comprise a phenoxy resin and an acrylic rubber.

The present invention also provides a first method for manufacturing a solar cell module comprising a plurality of photovoltaic cells and wiring members electrically connecting the photovoltaic cells to each other, the method comprising: disposing photovoltaic cell surface electrodes, the above-mentioned adhesive film for a solar cell electrode of the present invention, and the wiring members in this order; and joining the surface electrodes to the wiring members at a temperature equal to or less than 160° C.

The present invention also provides a second method for manufacturing a solar cell module comprising a plurality of photovoltaic cells and wiring members electrically connecting the photovoltaic cells to each other, the method comprising: disposing photovoltaic cell surface electrodes, the above-mentioned adhesive film for a solar cell electrode of the present invention, and the wiring members in this order; and joining the surface electrodes to the wiring members under a pressure equal to or less than 0.2 MPa.

The present invention also provides a third method for manufacturing a solar cell module comprising a plurality of photovoltaic cells and wiring members electrically connecting the photovoltaic cells to each other, the method comprising: disposing photovoltaic cell surface electrodes, the above-mentioned adhesive film for a solar cell electrode of the present invention, and the wiring members in this order; and joining the surface electrodes to the wiring members under a pressure equal to or less than 0.3 MPa.

In the second method for manufacturing a solar cell module of the present invention, it is possible to join the surface electrodes and the wiring members at a temperature equal to or less than 160° C.

The first and second methods for manufacturing a solar cell module of the present invention further comprises a sealing step of sealing the photovoltaic cells and the wiring members with a sealing material using a laminator, wherein it is possible to join the surface electrodes and the wiring members in the sealing step.

The third method for manufacturing a solar cell module of the present invention comprises the step of connecting the photovoltaic cells to the wiring members using an exclusive heat contact bonding machine suitable for connection between the wiring members and the photovoltaic cells using the adhesive film for a solar cell electrode, or comprises the sealing step of sealing the photovoltaic cells and the wiring members with the sealing material using the laminator, and can join the surface electrode to the wiring members in the sealing step. Examples of the exclusive heat contact bonding machine include an apparatus having a contact bonding head for contact bonding bus bars of photovoltaic cells on which wiring members are placed, from the top of the wiring members, and a heating mechanism provided on the contact bonding head.

The present invention also provides a solar cell module obtained by the first, second and third methods for manufacturing a solar cell module of the present invention. The photovoltaic cell surface electrodes are connected to the wiring members using the adhesive film for a solar cell electrode of the present invention, and thereby the solar cell module of the present invention has reduced adverse effects on the photovoltaic cells caused by heating or pressure, has sufficient solar cell characteristics, and can withstand use in an outdoor environment for a long time.

The present invention provides use of an adhesive film comprising a crystalline epoxy resin, a curing agent and a film forming material, for electrical connection between photovoltaic cell surface electrodes and wiring members. Here, it is preferable that the curing agent be a latent curing agent; it is preferable that the crystalline epoxy resin be a bisphenol type epoxy resin or a biphenyl type epoxy resin; and among them it is preferable that the crystalline epoxy resin be the bisphenol type epoxy resin.

In the use of the present invention, it is preferable that the above-mentioned bisphenol type epoxy resin be a compound represented by formula (2-1).

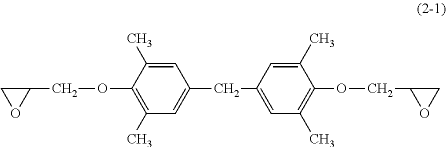

Here, it is preferable that, the above-mentioned film forming material comprise a phenoxy resin, and it is preferable that the above-mentioned film forming material comprise a phenoxy resin and an acrylic rubber.

According to the present invention, it is possible to provide the adhesive film for a solar cell electrode providing the photovoltaic cell capable of reducing adverse effects on the photovoltaic cells caused by heating or pressure and having sufficient solar cell characteristics, and the method for manufacturing a solar cell module using the same.

Since the adhesive film for a solar cell electrode of the present invention can sufficiently join the photovoltaic cell surface electrodes to the wiring members under temperature and pressure conditions in the laminating step of the sealing material, it is possible to simplify the manufacturing step of the solar cell module.

### BRIEF DESCRIPTION OF THE DRAWINGS

FIG. 1 is a schematic view showing the essential parts of a solar cell module according to the present invention;

FIG. 2 is an illustration for describing an embodiment of a method for manufacturing a solar cell module according to the present invention; and

FIG. 3 is a view showing a situation where photovoltaic cells are connected in series in two rows and two columns.

### DESCRIPTION OF THE PREFERRED EMBODIMENTS

Preferred embodiments of the present invention will now be described in detail, with reference to the drawings. Identical or corresponding parts in the drawings will be referred to by like reference numerals and will be described only once.

An adhesive film for a solar cell electrode of the present invention is used to connect photovoltaic cell electrodes and wires (wiring members) for linking photovoltaic cells in series and/or in parallel. Electrodes (surface electrodes) are formed on the front and rear sides of the photovoltaic cell to withdraw electricity.

Here, the surface electrodes may be made of known materials capable of providing electrical conduction, and examples thereof include common silver-containing glass paste, or silver paste, gold paste, carbon paste, nickel paste or aluminum paste obtained by dispersing various conductive particles in adhesive resins, and ITO formed by firing or vapor deposition. Silver-containing glass paste electrodes are preferably used among these from the viewpoint of heat resistance, conductivity, stability and cost.

Examples of the photovoltaic cell include a crystalline photovoltaic cell such as a single crystal silicon or polycrystal silicon photovoltaic cell, or a thin film photovoltaic cell such as an amorphous silicon, CIGS or CdTe thin film photovoltaic cell. Typical examples thereof include a photovoltaic cell having an Ag electrode and an Al electrode each provided as surface electrodes by screen printing or the like, on a substrate composed of at least one or more of single crystal, polycrystal and noncrystal of Si.

The adhesive film for a solar cell electrode of the present invention (hereinafter, abbreviated as an adhesive film of the present invention) contains an epoxy component, a curing agent and a film forming material, and contains a crystalline epoxy resin as the epoxy component. The adhesive film of the present invention may be composed of an insulating adhesive component, and may further contain conductive particles.

The crystalline epoxy resin in the present invention refers to one that contains a crystal section at room temperature (25° C.), and is characterized by having a crystalline structure regularly arranged in a part of a chain of a polymer. Typically, the crystalline epoxy resin refers to one having few bridges or branches of a molecule disadvantageous for crystallization and no large substituent, or being in a state where they have a regular steric configuration even if the crystalline epoxy resin has them.

The crystalline epoxy resin typically exists as a solid at a temperature lower than a crystallization temperature at which a resin component is cured, and is a liquid at a temperature equal to or higher than the crystallization temperature. That is, the crystalline epoxy resin is characterized in that although the crystalline epoxy resin exists as a stable solid in the crystal state of the crystalline epoxy resin, the crystalline epoxy resin is promptly melted from the crystal state when reaching the melting point, to be changed to a liquid having extremely low viscosity.

The crystalline epoxy resin is characterized in that a phase transition temperature to a liquid from a solid sharply appears and fluidity is rapidly increased at a temperature close to the melting point. The melting point may be measured using DSC (differential scanning calorimetry) and DTA (differential thermal analysis). For example, when an amount of heat is measured while a temperature is increased at a rate of 10° C./min from room temperature in the case of using the DSC, the melting point may be known from rapid change corresponding to absorption of heat caused by dissolution.

Examples of the crystalline epoxy resin include a biphenyl type epoxy resin, a bisphenol type epoxy resin, a stilbene type epoxy resin, a hydroquinone type epoxy resin and a thioether type epoxy resin.

Examples of the biphenyl type epoxy resin and the bisphenol type epoxy resin include epoxy resins represented by formulae (1) to (3).

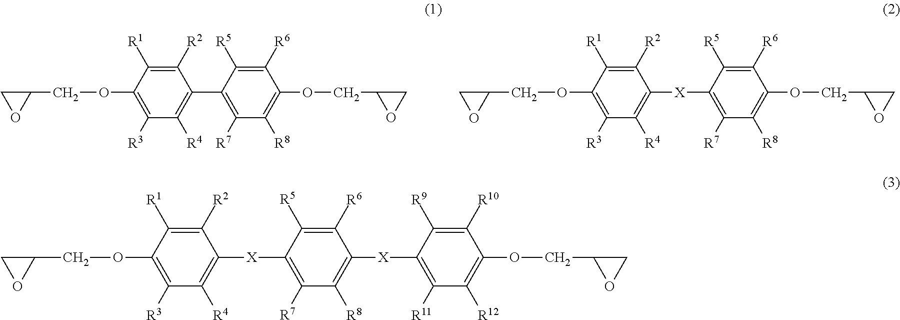

R¹ to R¹² in formulae (1) to (3) each represents a hydrogen atom or an alkyl group having 1 to 5 carbon atoms, and some or all of R¹ to R¹² may be the same or different. X in formulae (2) and (3) represents S, O, SO₂, CH₂ or C(CH₃)₂. Two X in formula (3) may be the same or different.

Examples of the crystalline epoxy resin can also include an epoxy resin represented by formula (4).

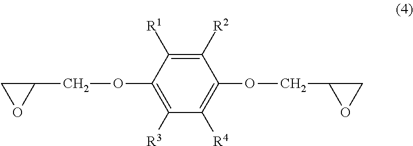

R¹ to R⁴ in formula (4) each represents a hydrogen atom or an alkyl group having 1 to 5 carbon atoms, and some or all of R¹ to R⁴ may be the same or different.

Examples of the commercially available crystalline epoxy resin include the trade names “YSLV-80XY” (bisphenol type epoxy resin, melting point: 80° C.), “YSLV-90CR” (bisphenol type epoxy resin, melting point: 89° C.), “GK-4137” (bisphenol type epoxy resin, melting point: 79° C.) and “YDC-1312” (hydroquinone type epoxy resin, melting point: 141° C.) and “YSLV-120TE” (thioether type epoxy resin, melting point: 120° C.) which are manufactured by Tohto Kasei Co., Ltd., and the trade names “YX8800” (biphenyl type epoxy resin, melting point: 109° C.), “YX4000” (biphenyl type epoxy resin, melting point: 105° C.) and YX 4000H (biphenyl type epoxy resin, melting point: 105° C.) which are manufactured by Mitsubishi Chemical Corporation. A crystalline epoxy resin described in WO2010/098066 may be also applied.

The melting point of the crystalline epoxy resin used in the present invention is preferably 50° C. to 200° C. from the viewpoint of being capable of maintaining film properties stabilized at room temperature and enabling flow and adhesion in a laminating step at about 150° C., more preferably 60° C. to 150° C., still more preferably 70° C. to 100° C. and particularly preferably 75° C. to 85° C.

When the adhesive film of the present invention contains a latent curing agent, it is preferable that the melting point of the crystalline epoxy resin be 60° C. to 120° C., and it is more preferable that the melting point thereof be 60° C. to 110° C. This is because the peak of the curing reaction temperature of the latent curing agent is present at about 120° C. and fluidity tends to be secured by mixing a crystalline epoxy resin having a melting point lower than about 120° C.

That is, it is more preferable to consider the peak of the reaction temperature of the latent curing agent to be used in order to select the crystalline epoxy resin. It is preferable that the melting point of the crystalline epoxy resin be in a range equal to or higher than 60° C. and equal to or lower than the peak of the curing reaction temperature of the latent curing agent.

From this viewpoint, it is preferable that the adhesive film of the present invention contain the bisphenol type epoxy resin or the biphenyl type epoxy resin as the crystalline epoxy resin, and further it is preferable that the adhesive film contain the bisphenol type epoxy resin in that the film sufficiently flows before the curing is started.

The bisphenol type epoxy resin is preferably a compound represented by formula (2-1).

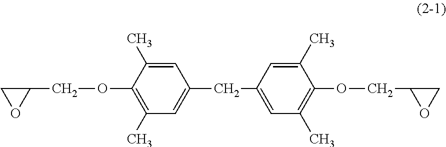

The curing agent used in the present invention is preferably a latent curing agent because the curing agent has relatively distinct active points for reaction initiation by heat and/or pressure, and is suitable for connection methods which involve heating/pressurizing steps. The epoxy-based adhesive containing the latent curing agent is particularly preferable because the epoxy-based adhesive can be cured in a short period of time, has good workability for connection and exhibits excellent adhesion by its molecular structure.

Examples of the latent curing agent include an anionic polymerizable catalyst-type curing agent, a cationic polymerizable catalyst-type curing agent and a polyaddition-type curing agent. Any of these may be used alone or in mixtures of two or more. Among these, the anionic or cationic polymerizable catalyst-type curing agent is preferable in that they have excellent fast-curing properties and do not require consideration in regard to chemical equivalents.

Examples of the anionic or cationic polymerizable catalyst-type curing agent include tertiary amines, imidazoles, hydrazide-based compounds, boron trifluoride-amine complexes, onium salts (sulfonium salts, ammonium salts or the like), amineimide, diaminomaleonitrile, melamine and derivatives thereof, polyamine salts and dicyandiamide, and modified products of the same can be also used. Examples of the polyaddition-type curing agent include polyamines, polymercaptane, polyphenol and acid anhydride.

When the tertiary amines or the imidazoles are used as the anionic polymerizable catalyst-type curing agent, the epoxy resin is cured by heating at a moderate temperature of about 150° C. for between several minutes and several hours. This is preferable because it comparatively lengthens the usable time (pot life).

Examples of the film forming material used in the present invention include a phenoxy resin, an acrylic rubber, a polyimide resin, a polyamide resin, a polyurethane resin, a polyester resin, a polyester urethane resin and polyvinyl butyral resins, and the phenoxy resin or the acrylic rubber is preferable.

The acrylic rubber is usually a copolymer containing (meth)acrylic acid alkyl ester as a copolymerization component. The copolymer can be obtained by the copolymerization of (meth)acrylic acid alkyl ester and other compound having a double bond in a molecule thereof, if needed, for example.

Examples of the above-mentioned (meth)acrylic acid alkyl ester include methyl(meth)acrylate, ethyl(meth)acrylate, propyl (meth)acrylate, butyl(meth)acrylate, hexyl(meth)acrylate and 2-ethylhexyl(meth)acrylate. These may be used either alone or in combination of two or more kinds thereof.

Examples of the above-mentioned other compound copolymerized if needed and having a double bond (an ethylenically unsaturated group) in a molecule thereof include acrylonitrile, glycidyl (meth)acrylate, 2-hydroxyethyl(meth)acrylate, 2-hydroxypropyl (meth)acrylate, (meth)acrylamide, allyl(meth)acrylate, N-vinyl pyrrolidone (meth)acrylate, allyl alcohol, (meth)acrylic acid, itaconic acid, crotonic acid, maleic acid and maleic anhydride. These may be used either alone or in combination of two or more kinds thereof.

There is no especial limitation on a method for polymerizing the acrylic rubber, and for example, a suspension polymerization method or the like may be used. Specifically, the acrylic rubber is polymerized by dropping the above-mentioned copolymerization component to a liquid in which a dispersing agent such as PVA and a polymerization initiator such as azobisisobutyronitrile or lauroyl peroxide are dispersed in an aqueous medium. Various polymerization methods such as solution polymerization are also possible if needed.

It is preferable that these acrylic rubbers have a functional group such as a glycidyl group, an acryloyl group, a methacryloyl group, a carboxyl group, a hydroxyl group or an episulfide group from the viewpoint of adhesion improvement. These functional groups may be introduced into the acrylic rubber using a compound having the functional group and a double bond in a molecule thereof as a copolymerization component, for example. The glycidyl group is particularly preferable in view of improving the crosslinkability of the acrylic rubber, and may be introduced into the acrylic rubber using as a copolymerization component a compound having a glycidyl group and a double bond in a molecule thereof, such as glycidyl(meth)acrylate, for example.

The crosslink density of the acrylic rubber may be adjusted by appropriately changing the content of the above-mentioned functional group. When the acrylic rubber is a copolymer containing a plurality of copolymerization components, it is preferable that the copolymerization rate of a compound having a functional group and a double bond in a molecule thereof be about 0.5 to 6.0% by mass.

When the glycidyl group is introduced into the acrylic rubber, it is preferable that the copolymerization rate of the glycidyl (meth)acrylate be 0.5 to 6.0% by mass, it is more preferable that the rate be 0.5 to 5.0% by mass and it is particularly preferable that the rate be 0.8 to 5.0% by mass. When the copolymerization rate of the glycidyl (meth)acrylate is within the above-mentioned range, the loose crosslinking of the glycidyl group is easily formed to tend to facilitate the suppression of gelling while securing adhesive strength. The glycidyl(meth)acrylate is easily incompatible with the epoxy resin, and tends to have excellent stress relaxation properties.

Among these, a phenoxy resin having weight-average molecular weight equal to or less than 100000 is preferable in view of high fluidity, and more preferably within the range of from 40000 to 60000. Among these, it is preferable that the weight-average molecular weight of the acrylic rubber be within the range of from 200000 to 2000000 in order to combine high reliability with film properties providing good handleability, it is more preferable that the weight-average molecular weight of the acrylic rubber be within the range of from 500000 to 1500000 and it is still more preferable that the weight-average molecular weight of the acrylic rubber be within the range of from 700000 to 1000000.

In the present invention, weight-average molecular weight and number-average molecular weight mean values measured using a calibration curve by standard polystyrene from gel permeation chromatograph (GPC) according to conditions shown in the following Table 1.

TABLE 1

| | |
|---|---|
| Apparatus | GPC-8020 manufactured by Tosoh |
| | Corporation |
| Detector | RI-8020 manufactured by Tosoh Corporation |
| Column | Gelpack manufactured by Hitachi Chemical |
| | Co., Ltd. |
| | GL-A-160-S + GL-A150-SG2000Hhr |
| Sample concentration | 120 mg/3 ml |
| Solvent | Tetrahydrofuran |
| Injection rate | 60 μl |
| Pressure | 30 kgf/cm² |
| Flow rate | 1.00 ml/min |

The adhesive film of the present invention may contain an adhesive component other than the above-mentioned crystalline epoxy resin, curing agent and film forming material.

Examples of the other adhesive component include a thermoplastic material and a curing material exhibiting curability by heat or light. In the embodiment, it is preferable that the adhesive film contain the curing material because of excellent heat resistance and moisture resistance after connection. Examples of a thermosetting resin include an epoxy resin other than the crystalline epoxy resin, a phenoxy resin, an acrylic resin, a phenol resin, a melamine resin, a polyurethane resin, a polyester resin, a polyimide resin and a polyamide resin. Among these, it is preferable that the adhesive film contain at least one of the epoxy resin, the phenoxy resin and the acrylic resin from the viewpoint of connection reliability.

Examples of the epoxy resin capable of being mixed except the crystalline epoxy resin include a bisphenol A-type epoxy resin, a bisphenol F-type epoxy resin, a bisphenol S-type epoxy resin, a phenol-novolac-type epoxy resin, a cresol-novolac-type epoxy resin, a bisphenol A/novolac-type epoxy resin, a bisphenol F/novolac-type epoxy resin, an alicyclic epoxy resin, a glycidyl ester-type epoxy resin, a glycidyl amine-type epoxy resin, a hydantoin-type epoxy resin, an isocyanurate-type epoxy resin and an aliphatic chain epoxy resin. These epoxy resins may be halogenated or hydrogenated. These epoxy resins may be also used in combination of two kinds or more thereof.

It is preferable that the adhesive film of the present invention contain a crystalline epoxy and a bisphenol F-type epoxy resin flowing at a temperature equal to or lower than about 100° C. in view of improving fluidity during connection.

In this case, it is possible to easily connect the photovoltaic cell surface electrodes and the wiring members without adversely affecting the photovoltaic cells. Since it becomes easy to mount the above-mentioned adhesive film collectively with the other sealing material by only a sealing step by laminating, it is possible to simplify the manufacturing step of the solar cell module more effectively by omitting a contact bonding step. Although the condition for the sealing step by laminating is usually determined by the crosslinking condition of EVA or the like typically used as the sealing material, typical examples thereof include a condition of holding at 150° C. for about 10 minutes.

The adhesive film of the present invention may also contain, in addition to the components described above, a modifying material such as a silane-based coupling agent, a titanate-based coupling agent or an aluminate-based coupling agent in order to improve adhesion or wettability, a dispersing agent such as calcium phosphate or calcium carbonate in order to improve the dispersibility of the conductive particles, and a chelate material to suppress silver or copper migration or the like.

The content of the epoxy component in the adhesive film of the present invention is preferably 20 to 70% by mass on the basis of the total amount of the adhesive film, more preferably 30 to 60% by mass, and still more preferably 40 to 50% by mass. It is possible to further improve good film properties before curing and adhesive strength after curing by mixing the epoxy component of the above-mentioned content.

The content of the crystalline epoxy resin in the adhesive film of the present invention is preferably 1 to 20% by mass on the basis of the total amount of the epoxy component, more preferably 5 to 15% by mass and still more preferably 7 to 10% by mass. By mixing the crystalline epoxy resin having the above-mentioned content, it is possible to maintain the stability of the film at room temperature and allow the crystalline epoxy resin sufficiently to flow during connection to bring the surface electrodes into direct contact with the wiring members, thereby more certainly obtaining conductivity and sufficiently obtaining the reliability of a wiring part after curing.

The content of the curing agent in the adhesive film of the present invention is preferably 10 to 50% by mass on the basis of the total amount of the epoxy component and the curing agent component, and more preferably 20 to 40% by mass.

It is preferable that the content of the film forming material in the adhesive film of the present invention be an amount sufficient to hold the hardness, elasticity and tack strength of the fabricated film with suitable easy-to-removal from a separator, and to avoid oozing or the like when being used as a film reel. It is preferable that the amount of the film forming material to be mixed be preferably 20 to 80 parts by mass based on 100 parts by mass of the total amount of the epoxy component and the curing agent component, and it is more preferable that the amount be 30 to 70 parts by mass.

Although it is also possible to use the phenoxy resin and the acrylic rubber as the film forming material, a low molecular weight phenoxy resin has excellent fluidity, and a high molecular weight acrylic rubber can apply elasticity to the film, thereby having an improving effect on reliability. Therefore, it is preferable to use the phenoxy resin in combination with the acrylic rubber, and thereby high fluidity can be expected at a low pressure (for example, 0.5 MPa or less, and preferably 0.3 MPa or less), and furthermore, reliability can be also secured. It is preferable that the amount of the acrylic rubber to be mixed be 5% by weight to 20% by weight based on a phenoxy resin component, and the amount is more preferably 10% by weight to 15% by weight.

The active temperature of the adhesive film of the present invention is preferably 40 to 200° C. The active temperature means a temperature at which the curing reaction of the adhesive film takes place. When the active temperature is less than 40° C., the difference between the active temperature and room temperature (25° C.) is reduced, which requires a low temperature in order to preserve the adhesive film, and on the other hand, when the active temperature is higher than 200° C., a member other than a connecting part is apt to be thermally affected. From the same viewpoint, it is more preferable that the active temperature of the adhesive be 50 to 150° C., and it is still more preferable that the active temperature be 70 to 130° C. The active temperature of the adhesive film can be determined from an exothermic peak temperature when a temperature is risen at 10° C./min from room temperature using DSC (differential scanning calorimeter) with the adhesive film as a sample.

The adhesive film of the present invention may further contain conductive particles. The adhesive film of the present invention in this case may function as a conductive adhesive film.

There are no particular restrictions on the conductive particles, and examples of the conductive particles include gold particles, silver particles, copper particles, nickel particles, gold-plated nickel particles, gold/nickel-plated plastic particles, copper-plated particles and nickel-plated particles. The conductive particles are preferably one that has a burr or spherical particle shape from the viewpoint of the embedding properties of the conductive particles to the surface irregularities of the adherend during connection. That is, the conductive particles having such a shape have high embedding properties relative to the complex irregular shapes of the surfaces of the solar cell surface electrodes or the wiring member, and have a high followability relative to variation such as vibration or expansion after connection, thereby enabling connection reliability to be further improved.

The particle diameter of the conductive particles is preferably within the range of from 1 to 50 μm, and more preferably within the range of from 1 to 30 μm.

The content of the conductive particles in the adhesive film of the present invention may be set as far as the adhesion of the adhesive film is not remarkably reduced, and for example, the content may be set to be equal to or less than 10% by volume on the basis of the total volume of the adhesive film, and preferably 0.1 to 7% by volume.

The adhesive film of the present invention may be fabricated by, for example, coating a release film such as a polyethylene terephthalate film with a coating solution containing the above-mentioned materials dissolved or dispersed in a solvent, and then removing the solvent. The adhesive film thus obtained has excellent dimensional precision of film thickness and pressure distribution during contact bonding, compared to paste-like conductive adhesives.

Although the example of the plastic film is shown as the release film as described above, an adhesive film integrated with the wiring member may be also produced using a metal film as the release film.

In the present invention, it is possible to supply the adhesive film in a state of an adhesive element provided with the release film and the adhesive film of the present invention provided on the release film.

The thickness of the adhesive film of the present invention can be controlled by adjusting a nonvolatile component in the above-mentioned coating solution, and by adjusting the gap of an applicator or a lip coater. It is preferable that the thickness of the adhesive film be 5 to 50 μm, and it is more preferable that the thickness be 10 to 35 μm.

The adhesive film of the present invention can be most preferably used for the photovoltaic cell. The solar cell is used as a solar cell module including a plurality of photovoltaic cells connected in series and/or in parallel and sandwiched between tempered glass or the like for environmental resistance, and provided with external terminals wherein the gaps are filled with a transparent resin. The adhesive film of the present invention is preferably used for connection between wiring members serving to connect a plurality of photovoltaic cells in series and/or in parallel and photovoltaic cell surface electrodes.

In a first embodiment of a method for manufacturing a solar cell module of the present invention, the photovoltaic cell surface electrodes, the above-mentioned adhesive film of the present invention, and the wiring members are disposed in this order, and the surface electrodes and the wiring members are joined at a temperature equal to or less than 160° C.

In a second embodiment of a method for manufacturing a solar cell module of the present invention, the photovoltaic cell surface electrodes, the above-mentioned adhesive film of the present invention, and the wiring members are disposed in this order, and the surface electrodes and the wiring members are joined under a pressure equal to or less than 0.2 MPa.

In the above-mentioned second embodiment of the method for manufacturing a solar cell module, it is possible to join the surface electrodes and the wiring members at a temperature equal to or less than 160° C. under a pressure equal to or less than 0.2 MPa. It is preferable that the temperature be equal to or less than 150° C.

In a third embodiment of a method for manufacturing a solar cell module of the present invention, the photovoltaic cell surface electrodes, the above-mentioned adhesive film of the present invention, and the wiring members are disposed in this order, and the surface electrodes and the wiring members are joined under a pressure equal to or less than 0.3 MPa.

In the above-mentioned third embodiment of the method for manufacturing a solar cell module, it is possible to achieve high reliable joining between the surface electrodes and the wiring members at a temperature equal to or less than 180° C. under a pressure equal to or less than 0.3 MPa using a heat contact bonding apparatus.

In the expressions for the above-mentioned terms “the surface electrodes and the wiring members are joined under a pressure equal to or less than 0.2 MPa” and “the surface electrodes and the wiring members are joined under a pressure equal to or less than 0.3 MPa”, the value of the pressure means a pressure in a portion to be joined. It is preferable that the lower limit of the pressure be 0.1 MPa from the viewpoint of productivity or the like.

When the joining is performed using a heat contact bonding apparatus provided with a contact bonding head having a heating mechanism, it is possible to set the pressure force of the contact bonding head based on the area of the portion to be joined. The area to be joined of the surface electrode and the wiring member in one location is determined by (a width of the wiring member)×(a cell length in a direction perpendicular to the width direction). Here, the surface electrode is provided over the entire cell length. The area to be joined may be not necessarily determined from the cell length, and may be determined by the length of the wiring member in use in a specification in which the length of the wiring member is shorter than the cell length.

Specifically, for example, when the width of the wiring member to be joined is 1.5 mm and the cell length is 156 mm, a pressure force set in the heat contact bonding apparatus can be determined from the following calculation, in order to set a pressure in the portion to be joined to 0.3 MPa (≈3 kgf/cm²). The following pressure force may be applied to the corresponding contact bonding head.

Target pressure=0.3 MPa(≈3 kgf/cm²)

Join area=0.15 cm×15.6 cm=2.34 cm²

Pressure force=(Join area)×(Target pressure)=2.34 cm²×3 kgf/cm²=7.02 kgf

When a plurality of portions to be connected are present and the contact bonding head corresponding to each of the portions is integrated, the above-mentioned area to be joined is determined by (a width of the wiring member)×(a cell length in a direction perpendicular to the width direction)×(number of the wiring members connected at one time).

The adhesive film of the present invention can adhere the surface electrodes to the wiring members in vacuum laminating used in the sealing step without necessarily requiring a heat contact bonding step of approximately 200° C. for adhesion between the surface electrodes of the solar cell and the wiring members.

That is, when the above-mentioned method for manufacturing a solar cell module is provided with the sealing step of sealing the photovoltaic cells and the wiring members with the sealing material using a laminator, it is possible to join the surface electrodes and the wiring members in the sealing step.

As a laminating condition in the sealing step, it is preferable to hold at 130° C. to 160° C. for 10 minutes or more, and it is more preferable to hold at 140° C. to 150° C. for 15 minutes or more. Although the laminating condition is fundamentally determined by the kind of the sealing material such as EVA, it is preferable that the laminating condition be set to a temperature at which an adhesive can be sufficiently cured, a holding time for which the adhesive can be sufficiently cured, and a temperature at which the adverse effects on the photovoltaic cell are reduced after the crosslinking condition of the EVA is met. When the temperature is too low, or the holding time is too short, the adhesive is not sufficiently cured, and problems may occur in adhesive strength or reliability, and when the temperature is too high, the adverse effects on the photovoltaic cell by the high temperature described above is apt to occur.

When the wiring members is supplied to the photovoltaic cells, the adhesive film of the present invention may be temporarily fixed to the surface electrodes by the tack strength of the adhesive film itself, or may be temporarily fixed by heat of about 80 to 120° C., and a pressure of about 1 MPa. A sealing material such as glass and EVA is laminated on a solar cell array in which the adhesive film is temporarily fixed and which is composed of the photovoltaic cells/the adhesive film/the wiring members, and the solar cell array is placed in a laminator, where a solar cell module is produced through the sealing step.

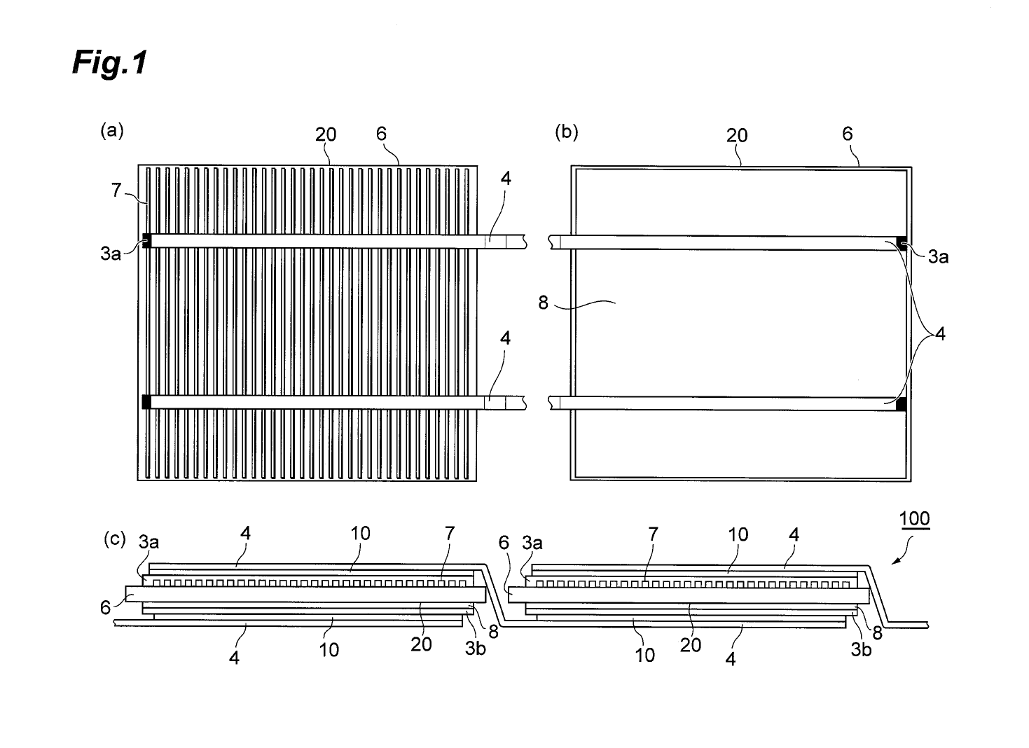

FIG. 1 is a schematic view showing the essential parts of the solar cell module according to the present invention, as an overview of a structure in which a plurality of photovoltaic cells are reciprocally wire-connected as one example. FIG. 1(A) shows the front side of the solar cell module, FIG. 1(B) shows the rear side, and FIG. 1(C) shows an edge view.

As shown in FIGS. 1(A) to (C), the solar cell module 100 has photovoltaic cells 20, with grid electrodes 7 and bus electrodes (surface electrodes) 3a formed on the front sides of semiconductor wafers 6 and rear electrodes 8 and bus electrodes (surface electrodes) 3b formed on the rear sides, the plurality of photovoltaic cells being reciprocally connected by wiring members 4. The wiring members 4 have one end connected to a bus electrode 3a as a surface electrode and the other end connected to a bus electrode 3b as a surface electrode, via adhesive films 10 according to the present invention.

Since the solar cell module 100 having this configuration has the surface electrodes and wiring members connected using the adhesive film of the present invention as described above, there is no adverse effect on the photovoltaic cells and it is possible to achieve sufficient connection reliability.

Examples of a method for evaluating whether the photovoltaic cells and the wiring members are suitably joined include current-voltage (I-V) curve measurement using a solar simulator. The joining can be evaluated by a value of a curve factor (F. F.) obtained by dividing the product of a short-circuit current (Isc) and open voltage (Voc) obtained at this time by a maximum current value (Pmax). In the solar cell module, it is preferable that the F. F. value be equal to or greater than 0.6, it is more preferable that the F.F. value be equal to or greater than 0.65, and it is still more preferable that the F.F value be equal to or greater than 0.7.

In order to judge whether the photovoltaic cells and the wiring members are suitably joined and the joining can withstand long-term use, it is possible to utilize an authentication test as shown in, for example, the IEC (International Electrotechnical. Commission) standard. There is a test sequence of IEC61215 shown for the solar cell module in the authentication test. In a Damp heat test (hereinafter, referred to as a DH test) therein, the solar cell module is stored in an atmosphere of a temperature of 85° C. and a humidity of 85% for 1000 hours, and the decreasing rate of optimum power (Pmax) obtained from an I-V curve is required to be equal to or less than 5%. It is important to clear the reliability test of an IEC standard level in actually utilizing the solar cell in order to evaluate the reliability of the solar cell module.

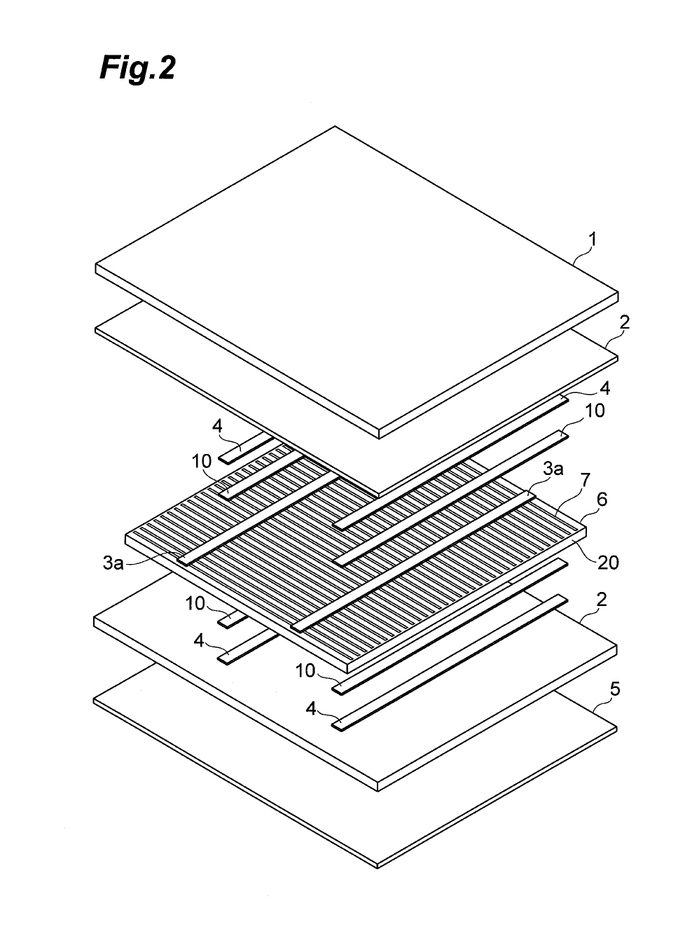

FIG. 2 is an illustration for describing an embodiment of a method for manufacturing a solar cell module according to the present invention. FIG. 2 shows a developed view of a laminated body prepared by disposing a glass plate 1, a sealing material 2, a wiring member 4, an adhesive film 10 of the present invention, a photovoltaic cell 20, an adhesive film 10 of the present invention, a wiring member 4, a sealing material 2, and a back sheet 5 in this order, as the laminated body placed in the laminator during the fabrication of the solar cell module through the sealing step described above. The wiring member 4 and the adhesive film 10 are disposed so as to correspond to the position of the surface electrode of the photovoltaic cell 20.

Examples of the glass plate 1 include a white plate tempered glass with a dimple for a solar cell. Examples of the sealing material 2 include an EVA sheet made of EVA. Examples of the wiring member 4 include a TAB wire obtained by dipping a Cu wire in solder or plating the Cu wire with the solder. Examples of the back sheet 5 include a PET-based or Tedlar-PET laminating material and a metal foil-PET laminating material.

### EXAMPLES

The present invention will now be described in greater detail based on Examples and Comparative Examples, with the understanding that the present invention is in no way limited to Examples.

<Fabrication of Adhesive Film and Fabrication of Solar Cell Module>

### Example 1

A phenoxy resin (product name: PKHC, manufactured by Union Carbide Corp., weight-average molecular weight: 45000) was dissolved in ethyl acetate to prepare 6.67 g of a 45% by mass solution. Then, after adding 4.5 g of a liquid epoxy resin containing a microcapsule-type latent curing agent (product name: NOVACURE HX-3941HP, manufactured by Asahi Kasei Chemicals Corp., epoxy equivalents: 185), 1.5 g of Cre-NovEp (product name: YDCN-703, manufactured by Tohto Kasei Co., Ltd.) which is a solid epoxy resin, 0.9 g of a bisphenol F-type epoxy resin (product name: YL983, manufactured by JER Co., Ltd.), and 0.9 g of bisphenol type crystalline epoxy (product name: YSLV-80XY, manufactured by Tohto Kasei Co., Ltd., melting point: 80° C.) to the solution, the mixture was stirred to obtain an adhesive composition.

The obtained adhesive composition (varnish) was applied to a polyethylene terephthalate film using an applicator (manufactured by Yoshimisu Corporation) and dried on a hot plate at 70° C. for 10 minutes to fabricate adhesive films having film thicknesses of 25 μm. The film thicknesses of the adhesive films were measured using a micrometer (ID-C112 manufactured by Mitutoyo Corporation).

Each of the obtained adhesive films was cut to the width (1.5 mm) of electrode wiring (material: silver glass paste, width: 1.5 mm) formed on a photovoltaic cell (156 mm×156 mm, polycrystal silicon), and interposed between TAB wires serving as the wiring members and manufactured by Hitachi Cable, Ltd. (A-TPS, manufactured by Hitachi Cable, Ltd.) and the above-mentioned photovoltaic cell surface electrode. Next, the photovoltaic cell to which the TAB wire was attached, a tempered glass (manufactured by AGC), ethylene vinyl acetate (EVA) and a back sheet were laminated in order of glass/EVA/photovoltaic cell/EVA/back sheet; the laminated body was placed in a vacuum laminator; and the laminated body was laminated on the condition that the vacuum laminator was evacuated at 150° C. for 5 minutes and held at 150° C. for 5 minutes, to fabricate a solar cell module.

The IV curve of the obtained solar cell module was measured using a solar simulator (WXS-155S-10, AM1.5G) manufactured by Wacom Electric Co., Ltd., and a curve factor F.F. was determined from the I-V curve.

It was confirmed that the curve factor F.F. was 0.649 and sufficient characteristics as the solar cell were obtained.

### Example 2

A solar cell module was fabricated in the same manner as in Example 1 except that an adhesive film was fabricated using varnish obtained by adding 0.83 g of Ni particles having a diameter of 10 μm to 6.0 g of an adhesive composition prepared in the same manner as in Example 1 and stirring the mixture. The curve factor F.F. of the obtained solar cell module was determined in the same manner as described above.

It was confirmed that the curve factor F.F. was 0.671 and sufficient characteristics as the solar cell were obtained.

### Example 3

A solar cell module was fabricated in the same manner as in Example 1 except that the amount of the bisphenol type crystalline epoxy (product name: YSLV-80XY, Tohto Kasei Co., Ltd., melting point: 80° C.) to be mixed in the adhesive composition of Example 1 was changed to 0.5 g. The curve factor F.F. of the obtained solar cell module was determined in the same manner as described above.

It was confirmed that the curve factor F.F. was 0.662 and sufficient characteristics as the solar cell were obtained.

### Example 4

A solar cell module was fabricated in the same manner as in Example 1 except that the amount of the bisphenol type crystalline epoxy (product name: YSLV-80XY, Tohto Kasei Co., Ltd., melting point: 80° C.) to be mixed in the adhesive composition of Example 1 was changed to 1.3 g. The curve factor F.F. of the obtained solar cell module was determined in the same manner as described above.

It was confirmed that the curve factor F.F. was 0.670 and sufficient characteristics as the solar cell were obtained.

### Example 5

A phenoxy resin (product name: PKHC, manufactured by Union Carbide Corp., weight-average molecular weight: 45000) was dissolved in ethyl acetate to prepare 7.78 g of a 45% by mass solution. Then, after adding a 15% by mass solution of 3.33 g in which 5.0 g of a liquid epoxy resin (product name: NOVACURE HX-3941HP, manufactured by Asahi Kasei Chemicals Corp., epoxy equivalents: 185) containing a microcapsule-type latent curing agent, 1.0 g of bisphenol type crystalline epoxy (product name: YSLV-80XY, Tohto Kasei Co., Ltd., melting point: 80° C.) and an acrylic rubber (product name: HTR-P3-TEA DR, manufactured by Hitachi Chemical Co., Ltd., weight-average molecular weight: 850000) were dissolved in toluene and ethyl acetate, to the solution, the mixture was stirred to obtain an adhesive composition.

The obtained adhesive composition (varnish) was applied to a polyethylene terephthalate film using an applicator (manufactured by Yoshimisu Corporation) and dried on a hot plate at 70° C. for 10 minutes to fabricate adhesive films having film thicknesses of 25 μm. The film thicknesses of the adhesive films were measured using a micrometer (ID-C112 manufactured by Mitutoyo Corporation).

Each of the obtained adhesive films was cut to the width (1.5 mm) of electrode wiring (material: silver glass paste, width: 1.5 mm) formed on a photovoltaic cell (156 mm×156 mm, manufactured by Qcells Corporation, Q6LTT3 polycrystal silicon), and interposed between TAB wires manufactured by Hitachi Cable, Ltd. (SSA-TPS, manufactured by Hitachi Cable, Ltd.) serving as the wiring members and the photovoltaic cell surface electrode. The TAB wires and the photovoltaic cell were connected by heating and contact bonding the TAB wires and the photovoltaic cell for 10 seconds so that the temperature of the adhesive film was 180° C. and the pressure applied to the join portion was 0.25 MPa, using an exclusive heat contact bonding machine (manufactured by Shibaura Mechatronics Corporation) equipped with a contact bonding head for contact bonding the bus bar of the photovoltaic cell on which the TAB wires were placed, from the top of the TAB wires, and a heating mechanism provided in the contact bonding head.

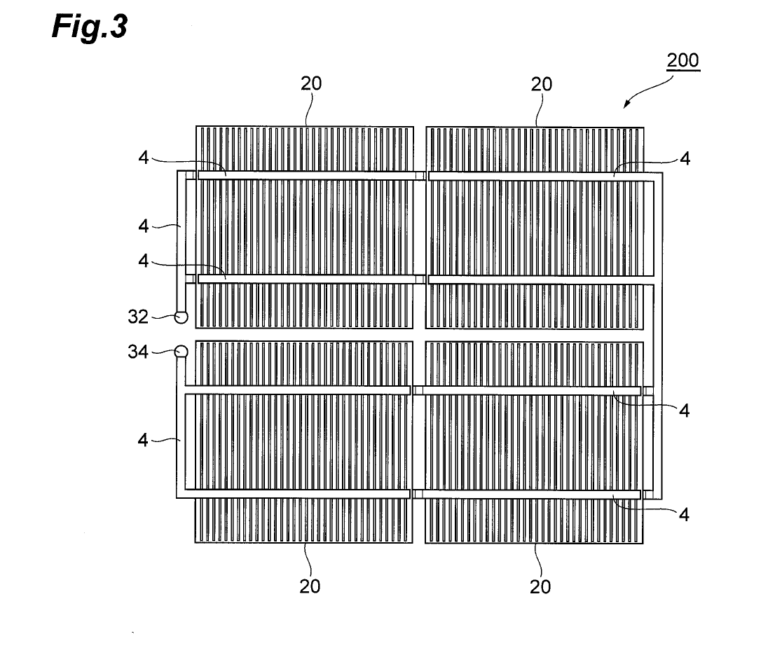

This step was performed in four photovoltaic cells, and as shown in FIG. 3, the wiring members 4 were connected, and photovoltaic cells 20 were disposed in two rows and two columns, and wired so as to be electrically series-connected. Next, the photovoltaic cells 20 to which the TAB wires were attached, a tempered glass (manufactured by AGC), ethylene vinyl acetate (EVA) and a back sheet were laminated in order of glass/EVA/photovoltaic cell/EVA/back sheet; the laminated body was placed in a vacuum laminator; and the laminated body was laminated on the condition that the vacuum laminator was evacuated at 150° C. for 5 minutes and held at 150° C. for 5 minutes, to fabricate a solar cell module 200.

The obtained solar cell module 200 was connected to a solar simulator (PVS1116i, AM1.5G) manufactured by Nisshinbo Mechatronics Inc. via connecting parts 32 and 34 of the end of the wiring member 4, and the IV curve was measured. A curve factor F.F. was determined from the I-V curve.

It was confirmed that the curve factor was 0.700 and the above-mentioned module had good characteristics as the solar cell. After a test (DH test) was performed as a reliability test with the solar cell module stored in a constant-temperature high-humidity bath set to a temperature of 85° C. and a humidity of 85% for 1000 hours, the decreasing rate of Pmax was 0.1%.

### Comparative Example 1

125 g of an acrylic rubber (product name: KS8200H, manufactured by Hitachi Chemical Co., Ltd., molecular weight: 850000) and 50 g of a phenoxy resin (product name: PKHC, manufactured by Union Carbide Corp., weight-average molecular weight: 45000) were dissolved in 400 g of ethyl acetate to prepare a 30% by mass solution. Then, after adding 325 g of a liquid epoxy resin (product name: NOVACURE HX-3941HP, manufactured by Asahi Kasei Chemicals Corp., epoxy equivalents: 185) containing a microcapsule-type latent curing agent to the solution, the mixture was stirred to obtain an adhesive composition. After 56 g of Ni particles having a diameter of about 10 μm was further added to the adhesive composition, the mixture was stirred.

An adhesive film was fabricated in the same manner as in Example 1 except that the composition obtained above was used, and a solar cell module was fabricated. The curve factor F.F. of the obtained solar cell module was determined in the same manner as described above.

The curve factor F.F. was 0.336 and sufficient characteristics as the solar cell were not obtained.

In Comparative Example 1, as reference, a tab wiring was performed on the following conditions using the adhesive film obtained in Comparative Example 1 by a conventional adhering method using a contact bonding tool, for example, as shown in Patent Documents (JP 2005-101519 A, JP 2007-214533 A and JP 2008-300403 A). A contact bonding tool (apparatus name: AC-S300, manufactured by Nikka Equipment & Engineering Co., Ltd.) was used for contact bonding at 180° C., 2 MPa for 10 seconds, to establish connection between the electrode wiring (surface electrode) on the front side of the photovoltaic cell and the TAB wires (wiring members) via the adhesive film, as shown in FIG. 1. Modularization was then performed in the same manner as in Example 1. When the curve factor F.F. of the obtained solar cell module was determined in the same manner as described above, the curve factor F.F. was 0.682 and sufficient characteristics as the solar cell were obtained.

### Comparative Example 2

A solar cell module was fabricated in the same manner as in Example 1 except that the bisphenol type crystalline epoxy (product name: YSLV-80XY, Tohto Kasei Co., Ltd., melting point: 80° C.) was not mixed with the adhesive composition. The curve factor F.F. of the obtained solar cell module was determined in the same manner as described above.

The curve factor F.F. was 0.464 and sufficient characteristics as the solar cell were not obtained.

### Comparative Example 3

A solar cell module of two rows and two columns was fabricated in the same manner as in Example 5 using the adhesive film obtained in Comparative Example 1. The solar cell module was evaluated in the same manner as in Example 5.

Although the curve factor F.F. was 0.639 and the solar cell module could be utilized as the solar cell, the decreasing rate of Pmax after a DH test was 8.1% to provide insufficient reliability.

The above results are shown in Table 2.

TABLE 2

| | F.F. |
|---|---|
| Example 1 | 0.649 |
| Example 2 | 0.671 |
| Example 3 | 0.662 |
| Example 4 | 0.670 |
| Example 5 | 0.700 |
| Comparative Example 1 | 0.336 |
| Comparative Example 1 | 0.682 |
| (contact bonding) | |
| Comparative Example 2 | 0.464 |
| Comparative Example 3 | 0.639 |

### REFERENCE SIGNS LIST

1 . . . glass plate, 2 . . . sealing material, 3 . . . surface electrode, 3a . . . bus electrode (surface electrode), 3b . . . bus electrode (surface electrode), 4 . . . wiring member, 5 . . . back sheet, 6 . . . semiconductor wafer, 7 . . . grid electrode, 8 . . . rear electrode, 10 . . . adhesive film, 20 . . . photovoltaic cell, 32, 34 . . . connecting part, 100, 200 . . . solar cell module

What is claimed is:

1. An adhesive film for a solar cell electrode used for electrical connection between photovoltaic cell surface electrodes and wiring members, the adhesive film comprising:
a crystalline epoxy resin;
a curing agent; and
a film forming material.

2. The adhesive film for a solar cell electrode according to claim 1, wherein the curing agent is a latent curing agent.

3. The adhesive film for a solar cell electrode according to claim 1, wherein the crystalline epoxy resin is a bisphenol type epoxy resin or a biphenyl type epoxy resin.

4. The adhesive film for a solar cell electrode according to claim 1, wherein the crystalline epoxy resin is a bisphenol type epoxy resin.

5. The adhesive film for a solar cell electrode according to claim 4, wherein the bisphenol type epoxy resin is a compound represented by formula (2-1).

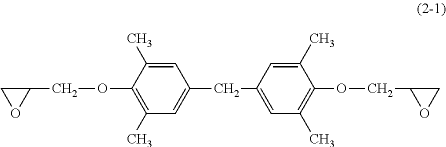

6. The adhesive film for a solar cell electrode according to claim 1, wherein the film forming material comprises a phenoxy resin.

7. The adhesive film for a solar cell electrode according to claim 1, wherein the film forming material comprises a phenoxy resin and an acrylic rubber.

8. A method for manufacturing a solar cell module comprising a plurality of photovoltaic cells and wiring members electrically connecting the photovoltaic cells to each other, the method comprising:
disposing photovoltaic cell surface electrodes, the adhesive film for a solar cell electrode according to claim 1, and the wiring members in this order; and
joining the surface electrodes to the wiring members at a temperature equal to or less than 160° C.

9. A method for manufacturing a solar cell module comprising a plurality of photovoltaic cells and wiring members electrically connecting the photovoltaic cells to each other, the method comprising:
disposing photovoltaic cell surface electrodes, the adhesive film for a solar cell electrode according to claim 1, and the wiring members in this order; and
joining the surface electrodes to the wiring members under a pressure equal to or less than 0.2 MPa.

10. A method for manufacturing a solar cell module comprising a plurality of photovoltaic cells and wiring members electrically connecting the photovoltaic cells to each other, the method comprising:
disposing photovoltaic cell surface electrodes, the adhesive film for a solar cell electrode according to claim 1, and the wiring members in this order; and
joining the surface electrodes to the wiring members under a pressure equal to or less than 0.3 MPa.

11. The method for manufacturing a solar cell module according to claim 9, wherein the surface electrodes and the wiring members are joined at a temperature equal to or less than 160° C.

12. The method for manufacturing a solar cell module according to claim 8, further comprising a sealing step of sealing the photovoltaic cells and the wiring members with a sealing material using a laminator,
wherein the surface electrodes and the wiring members are joined in the sealing step.

13. A solar cell module obtained by the method according to claim 8.

14. Use of an adhesive film comprising a crystalline epoxy resin, a curing agent and a film forming material, for electrical connection between photovoltaic cell surface electrodes and wiring members.

15. The use according to claim 14, wherein the curing agent is a latent curing agent.

16. The use according to claim 14, wherein the crystalline epoxy resin is a bisphenol type epoxy resin or a biphenyl type epoxy resin.

17. The use according to claim 14, wherein the crystalline epoxy resin is a bisphenol type epoxy resin.

18. The use according to claim 17, wherein the bisphenol type epoxy resin is a compound represented by formula (2-1).

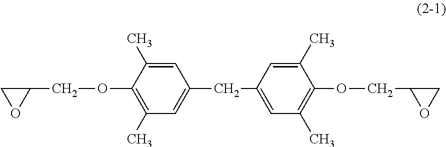

19. The use according to claim 14, wherein the film forming material comprises a phenoxy resin.

20. The use according to claim 14, wherein the film forming material comprises a phenoxy resin and an acrylic rubber.
